(19) United States
(12) Patent Application Publication
(10) Pub. No.: US 2016/0122880 A1
(43) Pub. Date: May 5, 2016

(54) METHOD AND DEVICE FOR FORMING PROTRUSION BY MASKING ON SURFACE OF BASIC MATERIAL

(71) Applicant: SEP, INC., Anyang-si, Gyeonggi-do (KR)

(72) Inventors: Sang Ro LEE, Anyang-si (KR); Jong Joo RHA, Seongnam-si (KR); Myung Jum PARK, Goyang-si (KR); Myoung Geun KIM, Seoul (KR); Yun Hwan KIM, Seoul (KR); Jae Hyung SEO, Busan (KR); Xin YUE, Anyang-si (KR); Ji Young LEE, Seoul (KR)

(21) Appl. No.: 14/896,101

(22) PCT Filed: Sep. 5, 2013
(86) PCT No.: PCT/KR2013/008036

§ 371 Date: Dec. 4, 2015

(30) Foreign Application Priority Data
Jun. 4, 2013 (KR) 10-2013-0063913

(51) Int. Cl. C23F 4/00; C23C 16/04; H01J 37/32; C23C 16/44

(52) U.S. Cl. CPC C23F 4/00; C23C 16/44; C23C 16/042; H01J 37/32522; H01J 37/3244

(57) ABSTRACT

A method for forming a protrusion by masking includes a mask formation step for forming a mask layer on a base material; an etching step for etching an area in which a mask is not formed on the base material, and a mask removal step for removing the mask layer. The mask formation step includes a step for forming at least one small mask, and a step for forming at least one big mask.

### TECHNICAL FIELD

The present invention relates to a method and device for forming protrusions by means of masking, and more particularly, to a method and device for forming protrusions by means of masking on the surface of a base material that is capable of processing the surface of the base material through the control of anti-reflection characteristics of the base material to improve anti-reflection functions and super water repellent functions.

### BACKGROUND ART

The reduction in the reflection of light in displays using touch functions like cellular phones, tablet PC and so on, cover windows of flat panel displays like TVs, computer monitors and so on, cover windows of solar cells, exterior glass of buildings, eyeglasses, and glasses for automobiles allows the efficiencies and visibility of the devices to be improved.

Generally, if there is a big difference between the refractive indexes of two media on the interface through which light passes, reflection occurs, and in this case, reflectivity is determined by the refractive index, the angle of incidence, and the angle of reflection between the two media, which is known as a Fresnel's law of reflection.

In case where display equipment has strong external light outside, even if the external light has low reflectivity, it has the almost same strength as the light emitted from the inside of the display equipment, thus making outdoor visibility lowered.

As the transmittance of solar light is raised like the cover glasses of solar cells, further, the quantity of power generation is accordingly increased. Therefore, reflection of light should be reduced. On the other hand, glare occurs by the reflection of light in the exterior glass of buildings and the glasses for automobiles, which has a lot of influences on safety problems, and therefore, there is a need to provide an anti-reflection function at an appropriate level.

So as to suppress the reflection occurring on the surface of glass, a substance having a thickness of λ/4 with respect to a wavelength λ of incident light and given value between the refractive index of air and the refractive index of glass is coated on the surface of glass. However, the suppression of reflection is limited to the specific wavelength λ, and accordingly, multiple thin films should be coated on the surface of glass so as to provide anti-reflection effects over the whole area of visible light.

Further, the coated layers with the multiple thin films have the limitation in the adhesion force to the substrate glass, so that they may peel off, and if the peeling occurs, colors on the thin films become unclear due to the irregularity on the surface of glass.

Accordingly, it is difficult that the anti-reflection technology using the multiple thin film coating is applied to surfaces like touch panels on which frequent contacts occur.

Recently, an anti-reflection technology using moth-eye effects has been proposed with many interests and studies. If nano-protrusions having smaller diameters than the wavelength band of visible light are formed on the surface of glass, the visible light does not recognize the existence of the nano-protrusions when passes through the surface of glass, and accordingly, the reflective indexes of the surface of glass are gradually varied along the shapes of the protrusions, thus lowering the reflectivity.

A variety of processes have been performed to apply the moth-eye effects to substrates, and in this case, advantages and disadvantages exist according to the respective processes. For example, a nano-imprinting technology is provided to form nano-structures on the surface of a mold by using liquid polymers, but undesirably, it does not achieve large area fabrication and high speed production.

Further, EUV (extreme ultraviolet) is used for nano-patterning in a semiconductor process like photo-lithography, which needs very expensive costs. Accordingly, there is a need to develop a technology capable of forming nano-masks on the surface of a transparent substrate to form nano-structures on the substrate, thus achieving large area fabrication and continuous processes.

Like this, if the nano-structures are formed on the substrate itself, they do not peel off at all, and even if damages occur due to external impacts, advantageously, they cannot be recognized by the eyes of human being.

On the other hand, since the reflectivity is varied in accordance with the wavelength range of incident light and the sizes and shapes of the nano-structures, there is a need to develop a technology capable of forming nano-masks on a large area substrate, while the sizes and distribution of the nano-masks are being freely adjusted.

### DISCLOSURE

### Technical Problem

Accordingly, the present invention has been made in view of the above-mentioned problems occurring in the prior art, and it is an object of the present invention to provide a method and device for forming protrusions by means of masking on a base material that is capable of manufacturing the base material having uniform AR characteristics over UV and IR wavelength areas (180 to 1400 nm).

It is another object of the present invention to provide a method and device for forming protrusions by means of masking on a base material that is capable of improving AR characteristics.

### Technical Solution

To accomplish the above-mentioned objects, according to a first aspect of the present invention, there is provided a method for forming protrusions by masking, including: the mask formation step of forming masks on a base material; the etching step of etching areas in which no masks are formed on the base material; and the mask removal step of removing the masks, wherein the mask formation step comprises the steps of: forming at least one or more small masks; and forming at least one or more big masks.

According to the present invention, desirably, in the mask formation step, metals having different melting points are supplied at the same temperature to form the small masks or the big masks, and in the mask formation step, otherwise, the same metal is supplied to have different treatment time or at different temperatures to form the small masks or the big masks. In the mask formation step, further, metals having different melting points are supplied to have different treatment time or at different temperatures to form the small masks or the big masks.

According to the present invention, desirably, in the mask formation step, metals having different melting paints in the same chamber are supplied to form the small masks or the big masks on the base material by means of physical vapor deposition, and otherwise, the same metal is supplied to a plurality of chambers operating for different treatment time or at different temperatures to form the small masks or the big masks on the base material by means of physical vapor deposition. In the mask formation step, further, metals having different melting points are supplied to a plurality of chambers operating for different treatment time or at different temperatures to form the small masks or the big masks on the base material by means of physical vapor deposition.

According to the present invention, desirably, in the mask formation step, a temperature of the base material is controlled in the same chamber, and a precursor is deposited through chemical vapor deposition to form the small masks or the big masks on the base material, and otherwise, different kinds of precursors are supplied to a plurality of chambers and deposited through chemical vapor deposition to form the small masks or the big masks on the base material.

To accomplish the above-mentioned objects, according to a second aspect of the present invention, there is provided a device for forming a protrusion by masking, including: a chamber; a base material mounting part formed in the chamber to mount a base material thereon; a metal supplying part for supplying a metal to the base material mounted on the base material mounting part by means of sputtering; and a temperature adjusting part for adjusting a temperature in the chamber.

According to the present invention, desirably, the base material mounting part includes a base material heater for heating the base material to a set temperature, and the base material heater has a plurality of thermocouples. On the other hand, the temperature adjusting part includes: a sensor for measuring a temperature in the chamber; and a chamber heater for adjusting the temperature in the chamber through power adjustment.

According to the present invention, desirably, the device further includes an in-line part for moving the base material so that through the driving of the in-line part, the metals having different melting points are supplied to the base material from the metal supplying part and the temperature in the chamber is kept at a given temperature through the temperature adjusting part.

According to the present invention, desirably, the chamber is divided into a plurality of chambers and the device further includes an in-line part for moving the base material in the plurality of chambers, so that through the driving of the in-line part, the same metal is supplied to the base material from the metal supplying part, and the respective chambers are operated for different treatment time or adjusted to different temperatures through the temperature adjusting part.

To accomplish the above-mentioned objects, according to a third aspect of the present invention, there is provided a device for forming a protrusion by masking, including: a chamber; a base material mounting part formed in the chamber to mount a base material thereon; a gas supplying part for depositing masks on the base material mounted on the base material mounting part by means of chemical vapor deposition; and a temperature adjusting part for adjusting a temperature of the base material.

According to the present invention, desirably, the temperature adjusting part includes: a sensor for measuring a temperature in the chamber; and a chamber heater for adjusting the temperature in the chamber through power adjustment. On the other hand, the gas supplying part supplies a given precursor to the base material, and the temperature adjusting part changes the temperature of the base material step by step.

According to the present invention, desirably, the chamber is divided into a plurality of chambers and the device further includes an in-line part for moving the base material in the plurality of chambers, so that through the driving of the in-line part, different precursors according to the respective chambers are supplied to the base material from the gas supplying part, and the respective base materials are adjusted to the same temperature as each other through the temperature adjusting part.

### Advantageous Effects

According to the present invention, the small masks or the big masks are formed on the base material, thus allowing the AR characteristics of the masks to be compositely expressed.

Accordingly, the base material having uniform AR characteristics over the UV and IR wavelength areas (180 to 1400 nm) can be manufactured.

### DESCRIPTION OF DRAWINGS

FIG. 1 is a flowchart showing a method for forming protrusions by means of masking according to the present invention.

FIG. 2 is a sectional view showing small masks and big masks formed on a base material in the mask formation step according to the present invention.

FIG. 3 is a sectional view showing one example of the mask formation step according to the present invention.

FIG. 4 is a sectional view showing another example of the mask formation step according to the present invention.

FIG. 5 is a sectional view showing the base materials after the etching step and the mask removal step.

FIG. 6 is a view showing the process for forming masks through a device according to a first embodiment of the present invention.

FIG. 7 is a view showing the process for forming masks through a device according to a second embodiment of the present invention.

FIG. 8 is a view showing the process for forming masks through a device according to a third embodiment of the present invention.

FIG. 9 is a view showing the process for forming masks through a device according to a fourth embodiment of the Present invention.

FIG. 10 is a table showing the division of masks according to sizes and the optical transmission characteristics by size according to the present invention.

FIG. 11 is a graph showing optical transmission characteristics of base materials by wavelength.

FIG. 12 is a graph showing the variations in sizes of masks formed by the same metal according to masking time.

FIG. 13 is a photograph showing the masks formed by time.

FIG. 14 is a graph showing the variations in the sizes of the masks formed by the same metal Bi according to the control of temperatures.

FIG. 15 is a photograph showing the masks formed at respective temperatures shown in the graph of FIG. 14.

### MODE FOR INVENTION

Hereinafter, the present invention will be in detail described with reference to the attached drawing.

FIG. 1 is a flowchart showing a method for forming protrusions by means of masking according to the present invention.

According to the present invention, a method for forming protrusions by masking, including: the mask formation step of forming masks on a base material; the etching step of etching areas in which no masks are formed on the base material; and the mask removal step of removing the masks, wherein the mask formation step comprises the steps of: forming at least one or more small masks; and forming at least one or more big masks.

The small masks and the big masks are determined by Table as shown in FIG. 10 and have different optical transmission characteristics according to their size. First type protrusions D1 have a size of 10 nm or under, but desirably have a size in the range of 50 to 150 nm in consideration of the optical transmittance by wavelength band. Second type protrusions D2 desirably have a size in the range of 150 to 300 nm and third type protrusions D3 desirably have a size in the range of 300 to 1000 nm. Fourth type protrusions D4 have a size in the range of 1 to 3 μm, but desirably have a size in the range of 1 to 2 μm in consideration of the optical transmittance.

The small masks include the first type protrusions or the second type protrusions, and the big masks include the third type protrusions or the fourth type protrusions. The small masks and the big masks are determined by anti-reflection AR characteristics. A detailed method for forming the small masks and the big masks will be explained later.

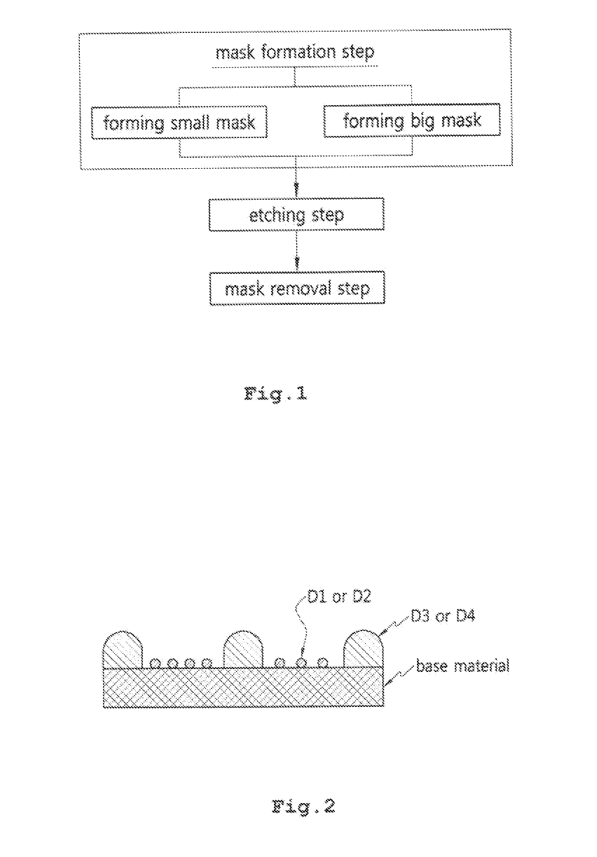

According to the present invention, the small masks and the big masks having different sizes are formed on a base material (for example, glass, plastic, film, substrate and the like), thus improving the AR characteristics of the base material. The fourth type protrusions or the third type protrusions formed on the base material have good anti-reflection effects against light having long wavelengths, and the first type protrusions or the second type protrusions formed on the base material have good anti-reflection effects against light having short wavelengths. According to the present invention, both of the small masks and the big masks are formed in the mask formation step, thus improving the anti-reflection characteristics against light on both of the long wavelength area and the short wavelength area. FIG. 2 is a sectional view showing the small masks and the big masks formed on the base material in the mask formation step of the method according to the present invention.

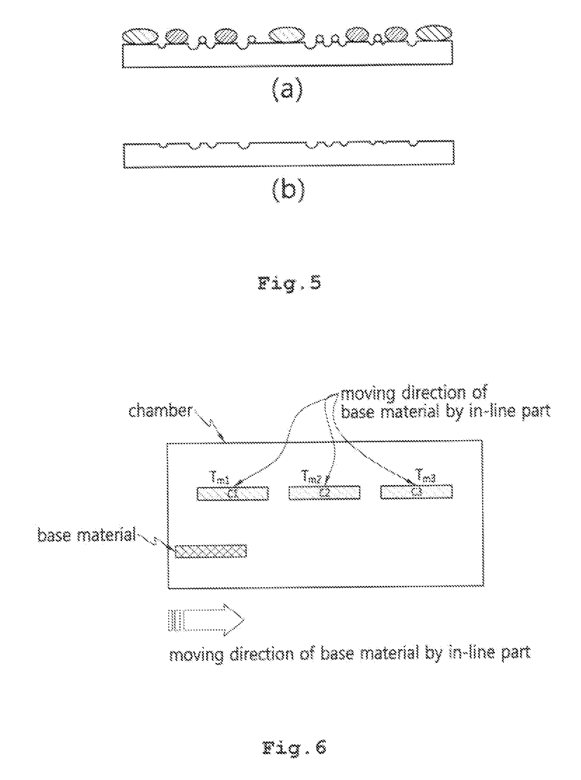

After the mask formation step, the etching step is conducted to etch areas in which no masks are formed on the base material. The etching step is shown in FIG. 5(a). The masks formed on the base material serve as a protection layer for preventing the base material from being etched.

In more detail, the etching step is conducted by mounting the base material on which the masks are formed on a vacuum RIE etcher, exhausting the interior of the etcher by means of a vacuum pump, and injecting CHF₃, Ar, and O₂ gases into the etcher to lower an etching pressure. Next, RF power is applied to generate plasma, and then, etching is performed with the ions and F radicals produced from the plasma.

In addition to CHF₃, gas like CF₄ and SF₆ in which element F is contained may be used as the gas for etching. Of course, the etching gas is not limited thereto. In the etching step, a degree of etching can be adjusted by the control in kinds of gas, mixing ratio of gas, power of RF power source, internal pressure of etcher, and etching time. After the base material is etched, the vacuum state in the interior of the etcher is released and a product is detached from the etcher, thus finishing the etching process.

After the etching step, the masks formed on the base material are removed. In the mask removal step, the masks remaining on the base material after the etching are removed, and in this case, a wet etching solution is diluted with water, and the masks are cleaned with the diluted solution. Hydrochloric acid liquid is used as the wet etching solution, and kinds and compositions of wet etching solutions and wet etching time are controlled in accordance with the kinds of masks. A mask removal result is shown in FIG. 5(b).

If the mask removal step is finished, protrusions are formed in correspondence with the patterns of the masks formed on the base material in the mask formation step. The protrusions include the first to fourth type protrusions, and the AR characteristics of the base material against both of short wavelengths and long wavelengths can be improved through the patterns of the protrusions.

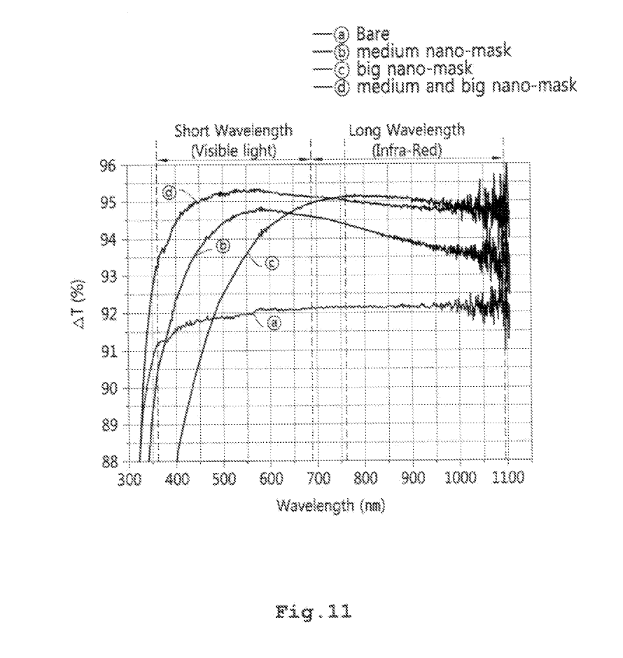

FIG. 11 is a graph showing optical transmission characteristics of base materials by wavelength. Referring to FIG. 11, \textcircled{a} indicates the case wherein no protrusion is formed, \textcircled{b} indicates the case wherein the second type protrusions having a size of about 200 nm are formed, \textcircled{c} indicates the case wherein the fourth type protrusions having a size of about 1 μm are formed, and \textcircled{d} indicates the case wherein both of the second type protrusions having a size of about 200 nm and the fourth type protrusions having a size of about 1 μm are formed.

The optical transmittances in the reference wavelength according to the above-mentioned conditions are listed in Table 1. Referring to Table 1 and FIG. 11, it can be appreciated that the formation of both of the small masks and the big masks enables the anti-reflection characteristics against the wavelengths (ultraviolet and infrared ray areas) between 180 to 1400 nm to be improved to increase the optical transmittances.

TABLE 1

| | Reference wavelength | Transmittance increasing |
|---|---|---|
| Division | (nm) | ratio to bare (%) |
| [symbol] Bare | 550/800 | — |
| [symbol] Small mask | 550 | 2.8 |
| [symbol] Big mask | 800 | 3.0 |
| [symbol] Small and big masks | 550/800 | 3.2/2.9 |

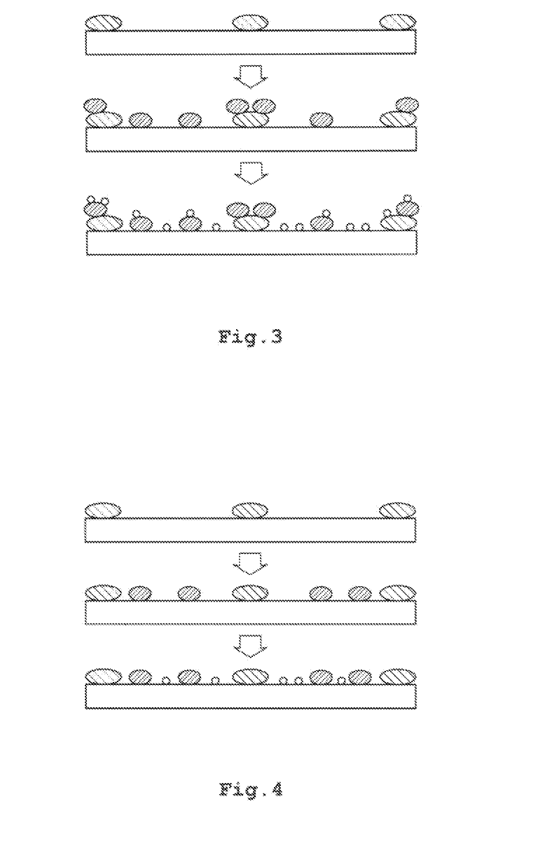

FIG. 3 is a sectional view showing one example of the mask formation step according to the present invention.

Through the mask formation step, as shown in FIG. 3, while a chamber and the base material are being kept at a given temperature, metals having different melting points are supplied to form the small masks or the big masks. According to the present invention, since the melting points or crystals are varied according to kinds of metals, the masks having different sizes can be formed at the same temperature.

For example, Bi and Sn have different melting points, and therefore, behaviors of particles deposited on the substrate having the same temperature as each other are different. At a given temperature, accordingly, the sizes of the masks formed by the Bi and those formed by the Sn are different from each other.

Under the above-mentioned characteristics, the small masks or the big masks are formed on the base material, thus achieving the objects of the present invention.

FIG. 4 is a sectional view showing another example of the mask formation step according to the present invention.

As shown in FIG. 4, the same metal is supplied at different temperatures or to have different treatment time to form the small masks or the big masks. According to the present invention, even if the masks are formed with the same metal, the sizes of the masks are different according to the masking time or temperatures, so that the sizes of the protrusions formed on the base material can be controlled.

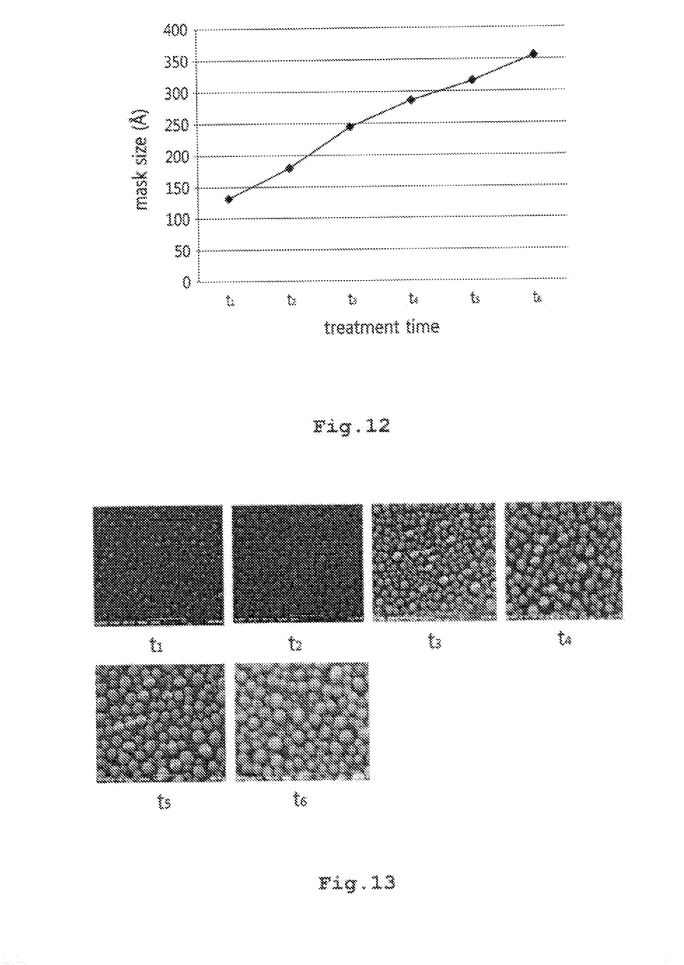

FIG. 12 is a graph showing the variations in the sizes of the masks formed by the same metal according to the masking time. In more detail, FIG. 12 shows the result wherein masks are formed by Sn at the same temperature under different treatment time. FIG. 13 is a photograph showing the masks formed by time.

As shown in FIGS. 12 and 13, if the masks are formed by Sn, the sizes of the masks become increased as the masking time becomes long. However, all kinds of materials do not have such relationships, and according to kinds of materials, the sizes of the masks become decreased as the masking time becomes long. According to the present invention, the masking time is controlled according to the characteristics of the materials so that the masks having various sizes can be formed.

On the other hand, the same metal is supplied at different temperatures to form the small masks or the big masks.

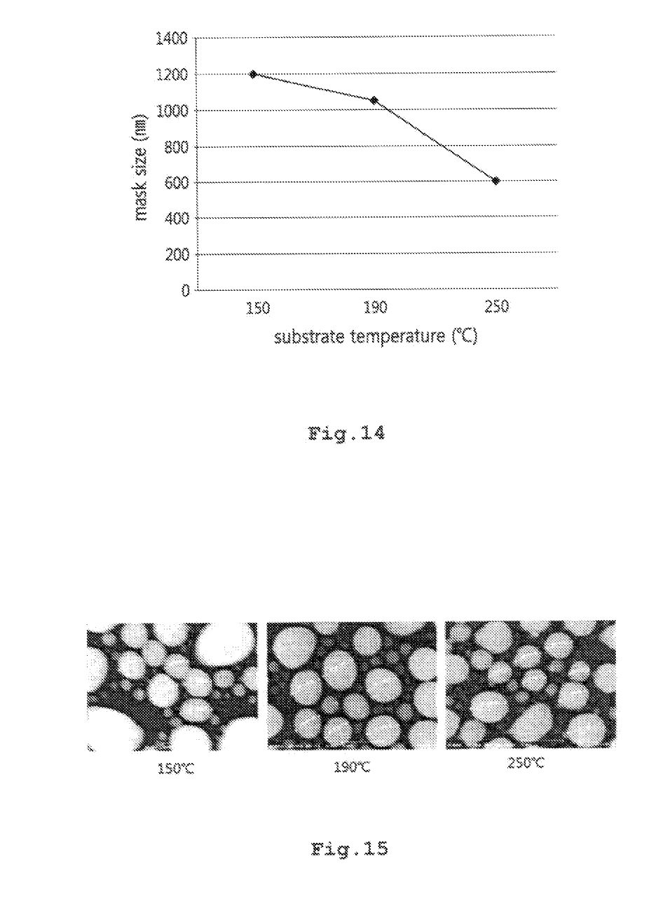

FIG. 14 is a graph showing the variations in the sizes of the masks formed by the same metal Bi according to the control of temperatures, and FIG. 15 is a photograph showing the masks formed at the respective temperatures in the graph of FIG. 14.

As shown in FIG. 14, the masks are formed by Bi as the temperatures of the base material (substrate) are varied. In this case, the sizes of masks have micro units (1.2 μm) at a low temperature (150° C.) and as the temperature of the base material is raised, the sizes of masks have nano units (600 nm). The actually formed masks are shown in FIG. 15.

However, as the temperature of the base material is raised, the sizes of masks are not necessarily reduced. In case of any material, the sizes of masks may be increased as the temperature of the base material is raised. Theoretically, large particles stably remain as a temperature is increased, but there are complicate factors, such as real interfacial energy, a degree of vacuum, shapes of particles, and influences of oxidation behavior according the quantity of oxygen in a chamber, so that as the temperature of the base material is raised, the sizes of masks may be increased or decreased according to the kinds of materials. Accordingly, the temperature is adjusted according to the characteristics of materials to control the sizes of masks.

According to the present invention, metals having different melting points may be supplied at different temperatures or to have different treatment time to form the small masks or the big masks. Accordingly, the masks having various sizes and shapes may be formed under the control in the selection of metals, temperatures, and treatment time, so that the protrusions having various sizes and shapes may be formed on the base material.

FIG. 6 is a view showing the process for forming masks through a device according to a first embodiment of the present invention.

According to the present invention, metals having different melting points in the same chamber are supplied to form small masks or big masks on a base material by means of physical vapor deposition PVD. The physical vapor deposition is a way of emitting particles from a source (for example, a sputtering target or crucible) through thermal energy or kinetic energy of ions to deposit the particles on the substrate. In more detail, the physical vapor deposition is classified into a sputtering method using the kinetic energy of ions and a vacuum deposition method using the thermal energy of ions.

In addition thereto, the physical vapor deposition further includes ion plating wherein after atoms evaporated in an anode are charged and then reach a cathode, they are discharged and attached to the substrate, which is similar to electroplating in the state of vapor state.

Through the physical vapor deposition, the metals having different melting points are supplied to form the masks on the base material, and the masks have different sizes and standard and non-standard distributions in accordance with the kinds of metals. According to the present invention, for example, the masks formed on the base material are shown in FIG. 3.

According to the present invention, on the other hand, the same metal is supplied to a plurality of chambers operating for different treatment time or at different temperatures to form small masks or big masks on the base material by means of the physical vapor deposition.

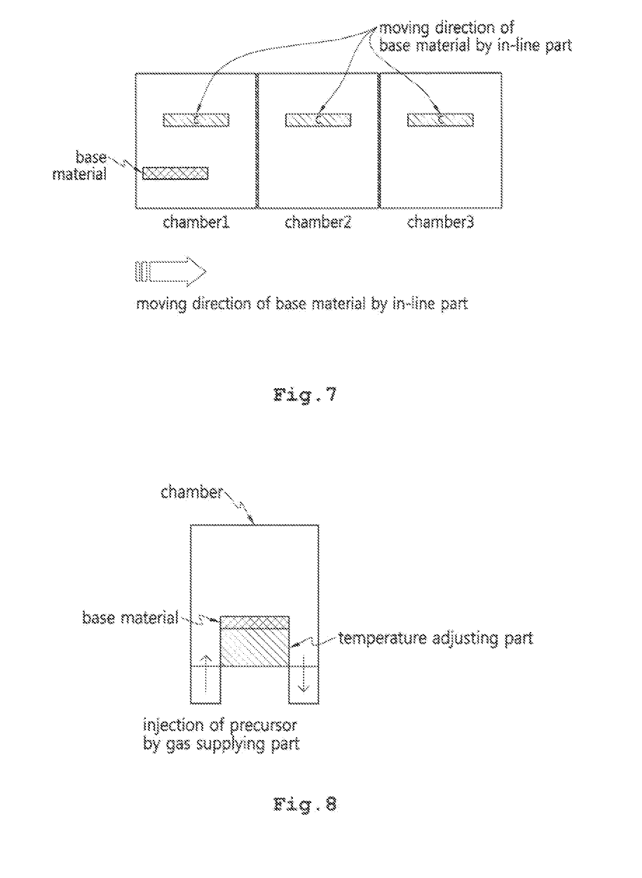

The process is shown in FIG. 7. The chambers operate for different treatment time or at different temperatures to form the masks as described with reference to FIGS. 12 to 15.

According to the present invention, on the other hand, metals having different melting points are supplied to a plurality of chambers operating for different treatment time or at different temperatures to form small masks or big masks on the base material by means of the physical vapor deposition, and in this case, the device for forming protrusions desirably has a structure as shown in FIG. 7. However, the number of chambers and the metal supply way are not limited to the examples as illustrated.

FIG. 8 is a view showing the process for forming masks through a device according to a third embodiment of the present invention.

According to the present invention, while a temperature of a base material is being controlled in the same chamber, a precursor is deposited through chemical vapor deposition CVD to form small masks or big masks on a base material.

The chemical vapor deposition is a process for injecting the precursor into the chamber to form the masks on the surface of the base material by using the reaction of the precursor. If the masks are formed by the chemical vapor deposition, the sizes of masks are different according to the temperatures of the base material, so that the small masks or the big masks are formed. The formed masks are similar to those in FIG. 4.

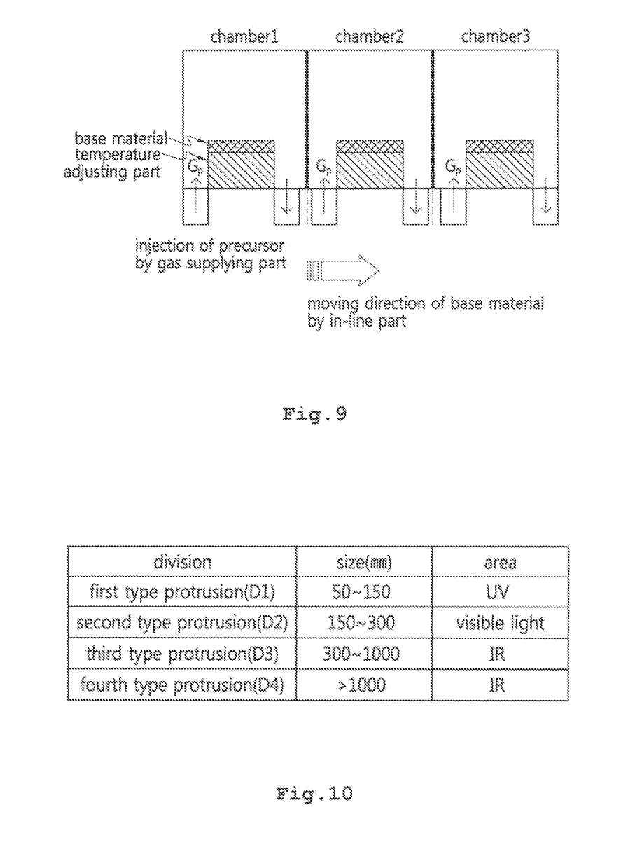

FIG. 9 is a view showing the process for forming masks through a device according to a fourth embodiment of the present invention. According to the present invention, different kinds of precursors are supplied to a plurality of chambers and deposited through chemical vapor deposition to form small masks or big masks on a base material. If the kinds of precursors are different according to the respective chambers, the masks having various sizes can be formed at the same temperature, and further, if a temperature of the base material is controlled, the masks may have more various sizes.

Hereinafter, the device for forming protrusions by means of masking (which is referred to as ‘device’) according to the present invention will be explained below.

According to the present invention, the device includes a chamber, a base material mounting part formed in the chamber to mount a base material thereon, a metal supplying part for supplying a metal to the base material mounted on the base material mounting part by means of sputtering, and a temperature adjusting part for adjusting a temperature in the chamber.

According to the present invention, the device forms small masks or big masks on the base material by means of the physical vapor deposition. The base material mounting part, the metal supplying part and the temperature adjusting part are not limited to specific positions, but desirably, they are arranged in such a manner as to allow the metal sputtered from the metal supplying part to be accurately targeted to the base material mounted on the base material mounting part. The examples of the small masks or big masks formed through the device of the present invention have been already mentioned above.

According to the present invention, the base material mounting part includes a base material heater for heating the base material to a set temperature, and the base material heater has a plurality of thermocouples. The base material can be masked by means of the physical vapor deposition at an optimized temperature made through the base material heater. Of course, a degree of deposition can be controlled through the adjustment of the temperature of the base material.

The thermocouples serve to evenly transmit heat over the base material and, do not have any specific shapes. If the size of the base material is big, the heat distribution on the base material in the mask formation process is changed and the deviation in the sizes of masks under the same condition is increased. Through the thermocouples, however, the heat generated from the base material heater is evenly transmitted to the base material and the deviation in the sizes of masks under the same condition is decreased.

On the other hand, the temperature adjusting part of the device according to the present invention includes a sensor for measuring a temperature in the chamber and a chamber heater for adjusting the temperature in the chamber through power adjustment. The temperature adjusting part is not included in the structures of FIGS. 6 and 7. The sensor serves to monitor the temperature in the chamber (in some cases, the temperature of the base material), and the chamber heater serves to apply heat to the chamber according to the mask formation conditions. The device of the present invention is controlled by power, and therefore, the temperature in the chamber can be controlled through the adjustment of the power.

On the other hand, the sensor and the chamber heater are not located on the same position as each other, but they are located independently of each other. The temperature adjusting part is formed of a single device, but it may be formed of a combination of various parts for adjusting the temperature in the chamber.

The device of the present invention further includes an in-line part for moving the base material. The in-line part has various shapes or ways, and accordingly, the configuration of the in-line part is not illustrated in the drawings. However, the sequential movement of the base material through the driving of the in-line part is shown in FIGS. 6 and 7. The base material is moved through the in-line part to apply various process conditions to the device of the present invention, thus achieving the automation in processes.

As shown in FIG. 6, the metals having different melting points are supplied to the base material from the metal supplying part through the driving of the in-line part, while the temperature in the chamber is being kept at a given temperature through the temperature adjusting part. As shown in FIG. 7, the in-line part is provided to move the base material in the plurality of chambers, and the same metal is supplied to the base material from the metal supplying part through the driving of the in-line part, while the chambers are being operated for different treatment time or adjusted to different temperatures by means of the temperature adjusting part.

According to the present invention, the temperature adjusting parts may be provided individually in the respective chambers, and otherwise, the temperatures of the respective chambers may be controlled by means of one temperature adjusting part. As mentioned above, the temperature adjusting part is formed of a single device, but it may be formed of a combination of various parts for adjusting the temperature in the chamber.

According to another preferred embodiment of the present invention, the device includes a chamber, a base material mounting part formed in the chamber to mount a base material thereon, a gas supplying part for depositing masks on the base material mounted on the base material mounting part by means of chemical vapor deposition, and a temperature adjusting part for adjusting a temperature of the base material.

According to the present invention, the device forms the small masks or big masks on the base material by means of the chemical vapor deposition. The base material mounting part, the gas supplying part and the temperature adjusting part are not limited to specific positions, but desirably, they are freely arranged in such a manner as to provide their functions.

The temperature adjusting part of the device according to the present invention includes a sensor for measuring a temperature in the chamber and a chamber heater for adjusting the temperature in the chamber through power adjustment. The sensor serves to monitor the temperature of the chamber or the base material, and the chamber heater serves to apply heat to the chamber according to the mask formation conditions. The device of the present invention is controlled by power, and therefore, the temperature of the base material can be controlled through the adjustment of the power.

On the other hand, the sensor and the chamber heater are not located on the same position as each other, but they are located independently of each other. The temperature adjusting part is formed of a single device, but it may be formed of a combination of various parts for adjusting the temperature in the chamber.

According to another embodiment of the present invention, the gas supplying part supplies a given precursor to the base material, and the temperature adjusting part changes the temperature of the base material step by step. The detailed description of the processes has been already mentioned above and shown in FIG. B.

According to still another embodiment of the present invention, a plurality of chambers is dividedly formed, and an in-line part is provided to move the base material in the plurality of chambers. Different precursors are supplied to the chambers from the gas supplying part through the driving of the in-line part, while the chambers are being adjusted to the same temperature as each other by means of the temperature adjusting part. The detailed description of the processes has been already mentioned above and shown in FIG. 9.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. A method for forming protrusions by masking, comprising:
the mask formation step of forming masks on a base material;
the etching step of etching areas in which no masks are formed on the base material; and
the mask removal step of removing the masks,
wherein the mask formation step comprises the steps of:
forming at least one or more small masks; and
forming at least one or more big masks.

2. The method according to claim 1, wherein in the mask formation step, metals having different melting points are supplied at the same temperature to form the small masks or the big masks.

3. The method according to claim 1, wherein in the mask formation step, the same metal is supplied to have different treatment time or at different temperatures to form the small masks or the big masks.

4. The method according to claim 1, wherein in the mask formation step, metals having different melting points are supplied to have different treatment time or at different temperatures to form the small masks or the big masks.

5. The method according to claim 2, wherein in the mask formation step, metals having different melting points in the same chamber are supplied to form the small masks or the big masks on the base material by means of physical vapor deposition.

6. The method according to claim 3, wherein in the mask formation step, the same metal is supplied to a plurality of chambers operating for different treatment time or at different temperatures to form the small masks or the big masks on the base material by means of physical vapor deposition.

7. The method according to claim 4, wherein in the mask formation step, metals having different melting points are supplied to a plurality of chambers operating for different treatment time or at different temperatures to form the small masks or the big masks on the base material by means of physical vapor deposition.

8. The method according to claim 1, wherein in the mask formation step, a temperature of the base material is controlled in the same chamber, and a precursor is deposited through chemical vapor deposition to form the small masks or the big masks on the base material.

9. The method according to claim 1, wherein in the mask formation step, different kinds of precursors are supplied to a plurality of chambers and deposited through chemical vapor deposition to form the small masks or the big masks on the base material.

10. A device for forming protrusions by masking, comprising:
a chamber;
a base material mounting part formed in the chamber to mount a base material thereon;
a metal supplying part for supplying a metal to the base material mounted on the base material mounting part by means of sputtering; and
a temperature adjusting part for adjusting a temperature in the chamber.

11. The device according to claim 10, wherein the base material mounting part comprises a base material heater for heating the base material to a set temperature, and the base material heater has a plurality of thermocouples.

12. The device according to claim 10, wherein the temperature adjusting part comprises:
a sensor for measuring a temperature in the chamber; and
a chamber heater for adjusting the temperature in the chamber through power adjustment.

13. The device according to claim 10, further comprising an in-line part for moving the base material so that through the driving of the in-line part, the metals having different melting points are supplied to the base material from the metal supplying part and the temperature in the chamber is kept at a given temperature through the temperature adjusting part.

14. The device according to claim 10, wherein the chamber is divided into a plurality of chambers and the device further comprises an in-line part for moving the base material in the plurality of chambers so that through the driving of the in-line part, the same metal is supplied to the base material from the metal supplying part, and the respective chambers are operated for different treatment time or adjusted to different temperatures through the temperature adjusting part.

15. A device for forming protrusions by masking, comprising:
a chamber;
a base material mounting part formed in the chamber to mount a base material thereon;
a gas supplying part for depositing masks on the base material mounted on the base material mounting part by means of chemical vapor deposition; and
a temperature adjusting part for adjusting a temperature of the base material.

16. The device according to claim 15, wherein the temperature adjusting part comprises:
a sensor for measuring a temperature in the chamber; and
a chamber heater for adjusting the temperature in the chamber through power adjustment.

17. The device according to claim 15, wherein the gas supplying part supplies a given precursor to the base material, and the temperature adjusting part changes the temperature of the base material step by step.

18. The device according to claim 15, wherein the chamber is divided into a plurality of chambers and the device further comprises an in-line part for moving the base material in the plurality of chambers, so that through the driving of the in-line part, different precursors according to the respective chambers are supplied to the base material from the gas supplying part, and the respective base materials are adjusted to the same temperature as each other through the temperature adjusting part.
